(19) United States
(12) Patent Application Publication
(10) Pub. No.: US 2024/0356535 A1
(43) Pub. Date: Oct. 24, 2024

(54) BLOOM FILTER FOLDING USING AN OPTIMIZED FOLD COUNT

(71) Applicant: WORKDAY, INC., Pleasanton, CA (US)

(72) Inventor: Michael SHULMAN, Auburndale, MA (US)

(21) Appl. No.: 18/304,719

(22) Filed: Apr. 21, 2023

(51) Int. Cl. H03H 17/02

(52) U.S. Cl. CPC H03H 17/02

(57) ABSTRACT

In some aspects, the techniques described herein relate to a method including: receiving a Bloom filter, the Bloom filter having an initial size and a first number of bits set; computing a number of folds for the Bloom filter by simulating a plurality of fold operations using the initial size and the first number of bits set; executing fold operations on the Bloom filter based on the number of folds to generate a folded Bloom filter, the folded Bloom filter having a size smaller than the initial size; and storing the folded Bloom filter.

### BACKGROUND

The disclosed embodiments are directed toward improvements in Bloom filters and, in particular, toward improvements in optimally sizing such filters.

A Bloom filter is a probabilistic data structure used for testing whether an element is a member of a set. It allows false positive matches (i.e., it may say an element is in the set when it is not), but it never produces false negatives (i.e., it will never say an element is not in the set when it is). A Bloom filter can be implemented as an array of bits and several hash functions. A given element can be converted into bit positions using the several hash functions. If all of the bit positions in the array of bits are set, the Bloom filter indicates a likely membership of the element to the set. Conversely, if at least one bit position is unset, the Bloom filter can definitively confirm the element is not in the set. For elements not in the set, the bit positions can be set to record membership.

The filter size (e.g., size of the array of bits) of a Bloom filter can impact its performance. Specifically, for a fixed number of elements in a set, a larger filter size will result in a smaller false positive rate. Conversely, a smaller filter size will result in a larger false positive rate. Generally, it is not possible to resize a Bloom filter once elements have been added to a set since insertions into the Bloom filter are not reversible (e.g., one cannot identify which element corresponds to the set bits). Thus, there exists a need in the art of Bloom filters to determine an optimal (or improved) size of a Bloom filter prior to inserting members into a set (i.e., when the number of unique values is unknown). The disclosed embodiments remedy these and similar problems in the art.

### BRIEF DESCRIPTION OF THE FIGURES

FIG. 1 is a block diagram illustrating a system for optimizing Bloom filters.

FIG. 2 is a flow diagram illustrating a method folding a Bloom filter.

FIG. 3 is a flow diagram illustrating a method for determining the optimal number of folds of a Bloom filter.

FIG. 4 is a block diagram illustrating a Bloom filter fold operation.

FIG. 5 is a block diagram illustrating computing device.

### DETAILED DESCRIPTION

The disclosed embodiments describe systems, devices, computer-readable media, and methods for determining a size of a Bloom filter based on an upper bound of a dataset. After all values in the dataset are inserted into the Bloom filter, the disclosed embodiments describe techniques for “folding” the Bloom filter (i.e., reducing its size by a desired amount) as many times as desired. For example, as described herein, a Bloom filter may be folded in half multiple times (i.e., reducing its size by half each time), although the disclosure is not necessarily limited to a specific size of fold.

In some aspects, the techniques described herein relate to a method including: receiving a Bloom filter, the Bloom filter having an initial size and a first number of bits set; computing a number of folds for the Bloom filter by simulating a plurality of fold operations using the initial size and the first number of bits set; executing fold operations on the Bloom filter based on the number of folds to generate a folded Bloom filter, the folded Bloom filter having a size smaller than the initial size; and storing the folded Bloom filter.

In some aspects, the techniques described herein relate to a method, further including determining the initial size based on properties of a data store used to populate the Bloom filter.

In some aspects, the techniques described herein relate to a method, wherein computing the number of folds includes iteratively simulating a series of fold operations to generate intermediate Bloom filters and determining when a false positive rate (FPR) of a given Bloom filter in the intermediate Bloom filters exceeds a preconfigured threshold.

In some aspects, the techniques described herein relate to a method, further including computing an FPR based on a number of expected bits set in the given Bloom filter and a total size of the given Bloom filter.

In some aspects, the techniques described herein relate to a method, wherein the number of expected bits set in the given Bloom filter is computed as:

$$\frac{1}{2} {b}_{s , curr} ( 2 - {P}_{c} ) ,$$

where b_{s,curr} represents a number of bits set in a current Bloom filter and P_{c} represents a probability of a bit collision between the current Bloom filter and the given Bloom filter.

In some aspects, the techniques described herein relate to a method, wherein executing the fold operations includes collapsing a plurality of fold operations into a single fold operation and executing the single fold operation on the Bloom filter.

In some aspects, the techniques described herein relate to a method, further including receiving a query including an element and determining if the element is in a dataset by determining if a plurality of bits of the folded Bloom filter are set.

In some aspects, the techniques described herein relate to a non-transitory computer-readable storage medium for tangibly storing computer program instructions capable of being executed by a computer processor, the computer program instructions defining steps of: receiving a Bloom filter, the Bloom filter having an initial size and a first number of bits set; computing a number of folds for the Bloom filter by simulating a plurality of fold operations using the initial size and the first number of bits set; executing fold operations on the Bloom filter based on the number of folds to generate a folded Bloom filter, the folded Bloom filter having a size smaller than the initial size; and storing the folded Bloom filter.

In some aspects, the techniques described herein relate to a non-transitory computer-readable storage medium, further including determining the initial size based on properties of a data store used to populate the Bloom filter.

In some aspects, the techniques described herein relate to a non-transitory computer-readable storage medium, wherein computing the number of folds includes iteratively simulating a series of fold operations to generate intermediate Bloom filters and determining when a false positive rate (FPR) of a given Bloom filter in the intermediate Bloom filters exceeds a preconfigured threshold.

In some aspects, the techniques described herein relate to a non-transitory computer-readable storage medium, further including computing an FPR based on a number of expected bits set in the given Bloom filter and a total size of the given Bloom filter.

In some aspects, the techniques described herein relate to a non-transitory computer-readable storage medium, wherein the number of expected bits set in the given Bloom filter is computed as:

$$\frac{1}{2} {b}_{s , curr} ( 2 - {P}_{c} ) ,$$

where b_{s,curr} represents a number of bits set in a current Bloom filter and P_{c} represents a probability of a bit collision between the current Bloom filter and the given Bloom filter.

In some aspects, the techniques described herein relate to a non-transitory computer-readable storage medium, wherein executing the fold operations includes collapsing a plurality of fold operations into a single fold operation and executing the single fold operation on the Bloom filter.

In some aspects, the techniques described herein relate to a non-transitory computer-readable storage medium, further including receiving a query including an element and determining if the element is in a dataset by determining if a plurality of bits of the folded Bloom filter are set.

In some aspects, the techniques described herein relate to a system including: a data store storing a dataset; a computing device configured to: receive a Bloom filter, the Bloom filter having an initial size and a first number of bits set, compute a number of folds for the Bloom filter by simulating a plurality of fold operations using the initial size and the first number of bits set, execute fold operations on the Bloom filter based on the number of folds to generate a folded Bloom filter, the folded Bloom filter having a size smaller than the initial size, and store the folded Bloom filter.

In some aspects, the techniques described herein relate to a system, the computing device further configured to determine the initial size based on properties of a data store used to populate the Bloom filter.

In some aspects, the techniques described herein relate to a system, wherein computing the number of folds includes iteratively simulating a series of fold operations to generate intermediate Bloom filters and determining when a false positive rate (FPR) of a given Bloom filter in the intermediate Bloom filters exceeds a preconfigured threshold.

In some aspects, the techniques described herein relate to a system, the computing device further configured to compute an FPR based on a number of expected bits set in the given Bloom filter and a total size of the given Bloom filter.

In some aspects, the techniques described herein relate to a system, wherein the number of expected bits set in the given Bloom filter is computed as:

$$\frac{1}{2} {b}_{s , curr} ( 2 - {P}_{c} ) ,$$

where b_{s,curr} represents a number of bits set in a current Bloom filter and P_{c} represents a probability of a bit collision between the current Bloom filter and the given Bloom filter.

In some aspects, the techniques described herein relate to a system, wherein executing the fold operations includes collapsing a plurality of fold operations into a single fold operation and executing the single fold operation on the Bloom filter.

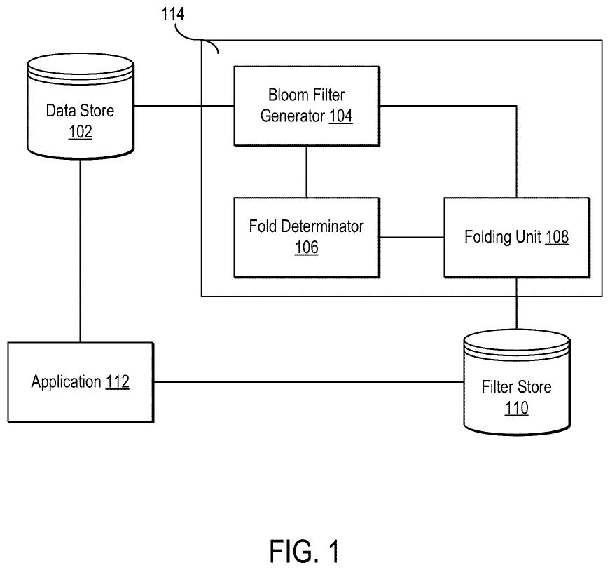

FIG. 1 is a block diagram illustrating a system for optimizing Bloom filters.

In some implementations, the system includes a data store 102. Data store 102 may comprise any type of storage medium for storing digital data. For example, data store 102 may comprise a relational database, NoSQL database, filesystem, key-value store, data lake, etc. In general, data store 102 may include multiple objects. As used herein, an object refers to an item of data organized within data store 102. For example, an object may be a row in a database table, a value in a key value store, or any other type of digital data. In some implementations, data store 102 can be populated by another computing system or device (not illustrated). For example, an online transaction processing (OLTP) system (not illustrated) may write objects to the data store 102. Similarly, an online analytical processing (OLAP) system may persist historical objects to data store 102. In some implementations, data store 102 may comprise a single device (e.g., single database server) although in other implementations, the data store 102 may comprise a storage system that includes multiple such devices.

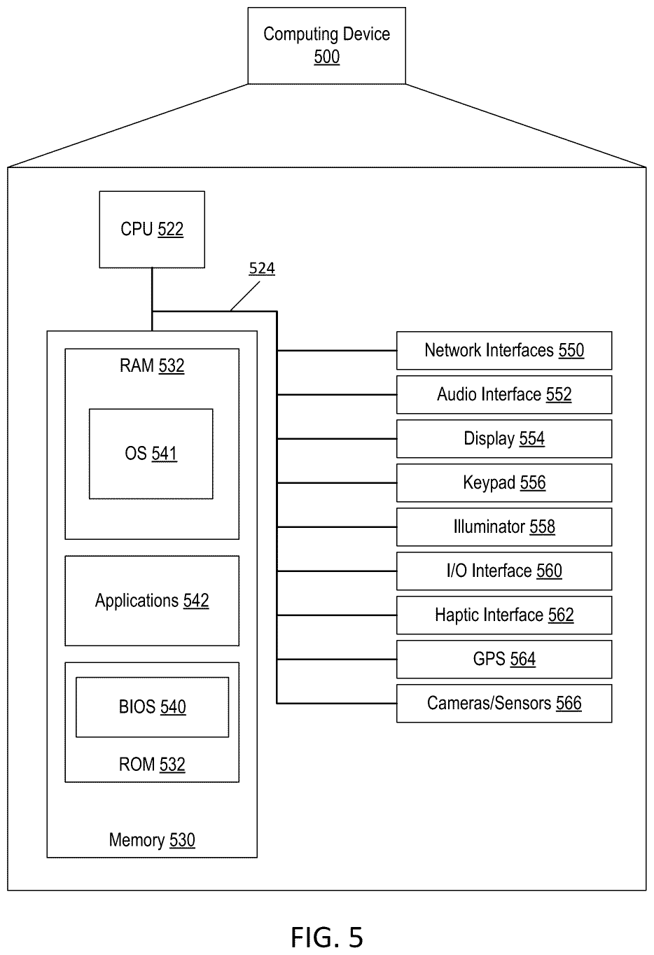

In some implementations, a computing device 114 may include a filter generator 104, fold determinator 106, and folding unit 108 and may be configured to generate a folded Bloom filter as described in more detail herein. In some implementations, computing device 114 may comprise a single computing device such as that depicted in FIG. 5 but in other implementations may comprise a network of computing devices working together.

A filter generator 104 is communicatively coupled to the data store 102. In some implementations, filter generator 104 is configured to build a filter used to act as a proxy for querying data store 102. In some implementations, filter generator 104 can generate a Bloom filter for data stored in data store 102. In some implementations, filter generator 104 can determine an initial size for the Bloom filter based on properties of the data store 102. Specifically, in some implementations, data stored in data store 102 may have a natural upper bound. For example, a survey system may request a survey from all employees at a given time. Such a system may store the survey results as objects in data store 102. As such, an upper bound corresponding to the number of surveys can be used to size the Bloom filter. Certainly, other scenarios may lend themselves to natural upper bounds. In some implementations, the physical or logical characteristics of data store 102 may define the upper bound. For example, a given data store 102 may only be capable of storing up to a fixed amount of data and this amount may be used as the upper bound. Notably, in contrast to existing techniques, filter generator 104 does not select a smallest Bloom filter and “scale up” by creating duplicative, but larger, Bloom filters. Rather, filter generator 104 generates a single, largest Bloom filter.

In some implementations, filter generator 104 may also populate the generated Bloom filter using data from data store 102. In some implementations, filter generator 104 may read data from data store 102 and insert the data into the generated Bloom filter. Specific details of inserting data into a Bloom filter are not described herein for the sake of clarity and existing techniques for populating a Bloom filter may be used. In brief, filter generator 104 can apply one or more hashing functions to each object in data store 102 to generate a list of bits to set in the Bloom filter. Filter generator 104 may then set the resulting bits for each object to populate the Bloom filter.

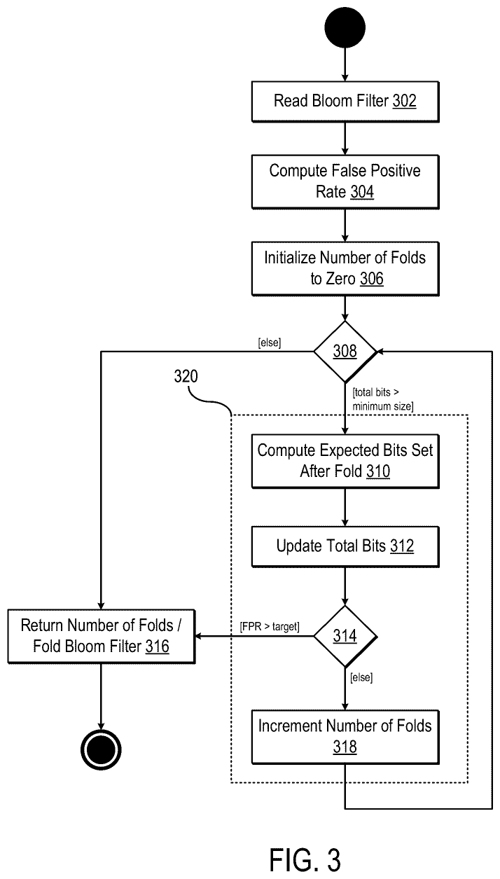

Filter generator 104 can then transmit the Bloom filter (or data representing the Bloom filter) to a fold determinator 106. In some implementations, fold determinator 106 can determine an optimal number of folds designed to reduce the size of the Bloom filter generated by fold determinator 106. Details of this process are described in FIG. 3 which are not repeated herein. In brief, the fold determinator 106 may analyze the Bloom filter or, alternatively, metadata of the Bloom filter to determine how many fold operations may applied to an input filter. For example, filter generator 104 may transmit the number of bits set in the initial filter as well as the total size of the filter to fold determinator 106. In some implementations, filter generator 104 may maintain a running tally of bits set when adding items to the filter and thus does not need to query the filter again to determine how many bits are set. In other implementations, the filter generator 104 may alternatively provide the filter itself to fold determinator 106 which can determine the number of bits set and total size.

Fold determinator 106 may iterate through multiple folds to simulate the folds. Fold determinator 106 can use these simulations to evaluate a fold's impact on the false positive rate (FPR) of the filter before and after folding. In some implementations, simulating folds can be done without actually performing the fold operations on the underlying filter data structure. As such, this simulation can be performed significantly faster than existing approaches to folding and unfolding filters by actually folding the data structure. In some implementations, this simulation can run until the FPR is too high (as defined by a preconfigured threshold) or the size of the filter is too small (also as defined by a preconfigured threshold).

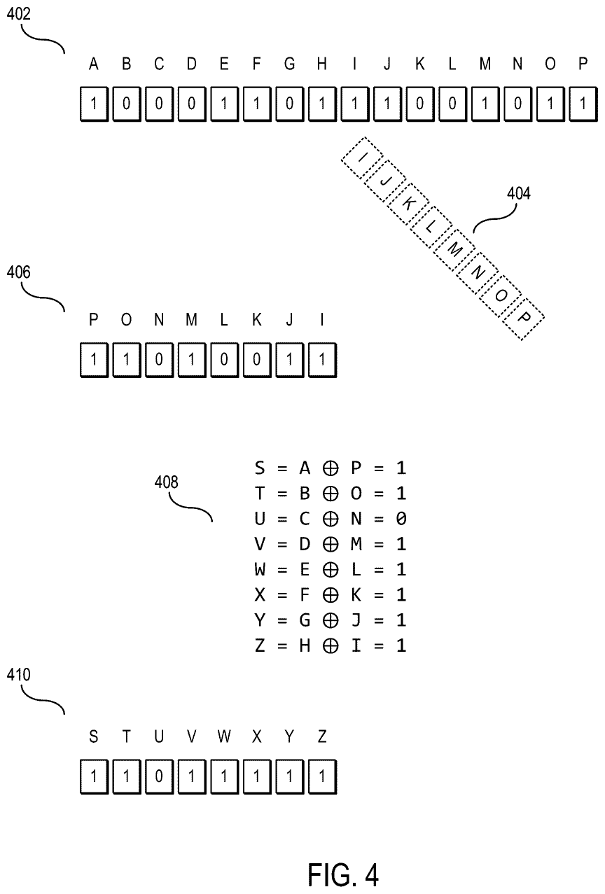

Fold determinator 106 may provide the optimal number of folds to folding unit 108. As illustrated folding unit 108 may also receive the initial Bloom filter from filter generator 104. Using the determined number of folds, folding unit 108 can perform a corresponding number of folds on the initial Bloom filter received from filter generator 104. FIG. 4 provides an example of a fold operation executed on a Bloom filter and that description is not repeated herein. In some implementations, folding unit 108 may perform an even fold on the Bloom filter. An even fold refers to folding a filter “in half” as depicted in FIG. 4. However, in other implementations, other folds may be used. For example, a trailing portion less than half may be folded. For example, in an eight element Bloom filter, elements 7 and 8 may be folded over elements 6 and 5, respectively. Certainly, other variations on where the fold point is may be considered. Similarly, while a reversing of the folded portion is described (and depicted in FIG. 4), in other scenarios, the fold may be “slid” over another portion. For example, in an eight element Bloom filter, elements 1 through 4 may be OR'd with elements 5 through 8, respectively (versus being OR'd with elements 8 through 5, respectively). In yet other implementations, the folded elements may be randomized or otherwise distributed. For example, in an eight element Bloom filter, elements 1 through 4 may be OR'd with elements 5, 8, 6, and 7, respectively or another random ordering.

In some implementations, folding unit 108 may execute the fold operations sequentially, that is performing each fold separately. In other implementations, folding unit 108 may collapse the operations into a single fold operation. For example, turning briefly to FIG. 4, the sixteen-element Bloom filter may be folded in a single step by computing the required operations. As illustrated, a first fold results in equations 408. A second fold would further require S⊕Z=b₁, T⊕Y=b₂, U⊕X=b₃, and V⊕W=b₄. These four operations can be combined with equations 408 to generate a single set of operations to generate the resulting four-element Bloom filter:

$${b}_{1} = S ⊕ Z = ( A ⊕ P ) ⊕ ( H ⊕ I ) \qquad Equation 1$$

$${b}_{2} = T ⊕ Y = ( B ⊕ O ) ⊕ ( G ⊕ J )$$

$${b}_{3} = U ⊕ X = ( C ⊕ N ) ⊕ ( F ⊕ K )$$

$${b}_{4} = V ⊕ W = ( D ⊕ M ) ⊕ ( E ⊕ L )$$

As illustrated, the final bits of the Bloom filter (folded twice) can be computed based on the original elements. As such, in some implementations, folding unit 108 may execute a single fold encompassing multiple interim folds.

After folding the initial Bloom filter, folding unit 108 can persist the folded Bloom filter in filter store 110. In some implementations, filter store 110 may be a filesystem, database, in-memory storage, cache (e.g., key-value store or similar mechanism), etc. Indeed, in some implementations, filter store 110 may comprise an in-memory store. In such an implementation, the initial Bloom filter can be generated, and the folded Bloom filter be maintained in local memory given its reduced size, thus allowing for fast access to the filter. In some implementations, the initial Bloom filter can also be stored in filter store 110 in a persistent or volatile data storage.

As illustrated an application 112 may issue requests to the filter store 110. Specifically, in some implementations, application 112 may query the filter store 110 to determine if a given element is in the data store 102 using the folded Bloom filter as a proxy. Specifically, the folded Bloom filter (and indeed all Bloom filters) may incorrectly identify elements as existing in a set, but will never provide false negatives. As such, application 112 may comprise an application that is programmed to access elements in data store 102 if they exist. Such an application may query the folded Bloom filter first to determine if a request should be sent to data store 102. If the folded Bloom filter returns a value indicating the requested element is not in the filter, application 112 may forego accessing data store 102 (which may incur lengthier network and disk accesses). All uses of Bloom filters may be employed by the system given that the system retains the properties of Bloom filters in the folded Bloom filter.

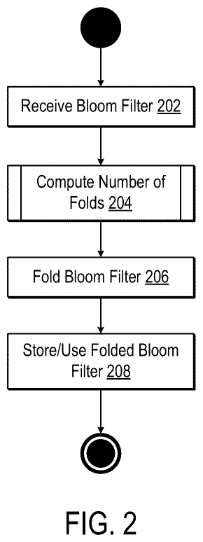

FIG. 2 is a flow diagram illustrating a method folding a Bloom filter.

In step 202, the method can include receiving a Bloom filter.

The Bloom filter may comprise an array of bits set or unset based on hashing elements to insert into a set. This array of bits may have a first fixed size wherein a portion of the bits is set to one based on the hash functions used to map elements to bit positions. In some implementations, the Bloom filter may be populated with a set of elements. For example, in some implementations, a dataset of a fixed (or otherwise known or predicted) size may be accessed and a corresponding Bloom filter with a fixed size created. Thereafter, elements of the dataset can be added to the Bloom filter, setting the various bits along the way. In general, and as used herein, a Bloom filter stores an array of binary digits. For example, a binary one represents a “set” bit while a binary zero represents an “unset” bit. Bits of a Bloom filter are set based on the bits output by a hash function when a new element is passed into the hash function.

In step 204, the method can include computing the number of folds available for the Bloom filter received in step 202. Details of this step are provided more fully in the description of FIG. 3 which is not repeated herein. In brief, the method of FIG. 3 will provide the number of folds to execute for the Bloom filter. The method of FIG. 3 can determine this number by simulating folds using metadata of the Bloom filter (e.g., the number of bits set and the total size of the filter) and need not perform array operations which incur significant computational power. In some implementations, step 204 can thus include iteratively simulating a series of fold operations to generate intermediate Bloom filters and determining when an FPR of a given Bloom filter in the intermediate Bloom filters exceeds a preconfigured threshold.

In step 206, the method can include folding the Bloom filter based on the number of folds identified in step 204.

In some scenarios, the number of folds may be zero and the method may simply not fold the Bloom filter, returning the original Bloom filter. However, in most scenarios, the number of folds is one or more. As such, in step 206, the method may fold the Bloom filter one or more times in such a scenario. Reference is made to FIG. 4, which illustrates a fold operation.

In some implementations, step 206 can include performing an even fold on the Bloom filter. An even fold refers to folding a filter “in half” as depicted in FIG. 4. However, in other implementations, other folds may be used. For example, a trailing portion less than half may be folded. For example, in an eight element Bloom filter, elements 7 and 8 may be folded over elements 6 and 5, respectively. Certainly, other variations on where the fold point is may be considered. Similarly, while a reversing of the folded portion is described (and depicted in FIG. 4), in other scenarios, the fold may be “slid” over another portion. For example, in an eight element Bloom filter, elements 1 through 4 may be OR'd with elements 5 through 8, respectively (versus being OR'd with elements 8 through 5, respectively). In yet other implementations, the folded elements may be randomized or otherwise distributed. For example, in an eight element Bloom filter, elements 1 through 4 may be OR'd with elements 5, 8, 6, and 7, respectively or another random ordering.

In some implementations, step 206 can include executing the fold operations sequentially, that is performing each fold separately. In other implementations, step 206 can include collapsing the operations into a single fold operation. For example, turning briefly to FIG. 4, the sixteen-element Bloom filter may be folded in a single step by computing the required operations. As illustrated, a first fold results in equations 408. A second fold would further require S⊕Z=b₁, T⊕Y=b₂, U⊕X=b₃, and V⊕W=b₄. These four operations can be combined with equations 408 to generate a single set of operations to generate the resulting four-element Bloom filter as depicted in Equation 1.

FIG. 4 is a block diagram illustrating a Bloom filter fold operation.

As illustrate, an initial Bloom filter 402 may be folded into a folded Bloom filter 410. The initial Bloom filter 402 has a size of sixteen (positions A through P) and is populated with various bits set (A, E, F, H, I, J, M, O, P). During a fold operation, one half of the initial Bloom filter 402 (bits I through P) are “rotated” or folded over the other half (bits A through H). This rotation is illustrated as rotation 404 which results in a fold 406. Certainly, when implemented, other techniques can be used to simulate such a folding or rotation. For example, the last half of the initial Bloom filter 402 may be simply reverse to obtain reversed list equal to fold 406. Next, the first half of the initial Bloom filter 402 (bits A through H) are logically OR'd with fold 406, as illustrated in equations 408. The results of equations 408 generate a new, folded Bloom filter (folded Bloom filter 410).

The above process can be repeated depending on various stop conditions (discussed in FIG. 3). For example, bits S, T, U, and V may be OR'd with bits Z, Y, X, W to obtain a four-bit Bloom filter array (which, coincidentally, will be all ones). As illustrated in FIG. 4, and discussed further in FIG. 3, folding a Bloom filter may (and often will) increase the false positive rate since a smaller number of bits is representing the same amount of input data. Thus, the disclosed embodiments monitor the error rate (as well as filter size) to ensure that the false positive rate stays within an acceptable range.

Returning now to FIG. 2, in step 208, the method can include storing and using the folded Bloom filter. In the various embodiment, the Bloom filter can be stored in any suitable mechanism such as a filesystem, database, in-memory storage, cache (e.g., key-value store or similar mechanism), etc. The Bloom filter can then be used to query for membership of new elements using standard techniques for querying a Bloom filter which are not described herein. As discussed, the use of folding can drastically decrease the storage capacity needed to store an initial Bloom filter. Indeed, the storage capacity can be improved exponentially as 2ₖ where k represents the number of folds. Thus, if a single fold is performed, a two-fold improvement in storage capacity (i.e., half the required capacity) is required, if two folds are performed a four-fold improvement is obtained, etc.

As indicated above, with respect to step 204, a method for determining the optimal number of folds for a given Bloom filter is described next which can ensure that the optimal number of folds, when considering the false positive rate, is achieved. The following method does not require actual folding of the Bloom filter and thus avoids the need for computationally expensive list traversals, but instead relies on the number of bits set in the Bloom filter and the total size of the Bloom filter.

FIG. 3 is a flow diagram illustrating a method for determining the optimal number of folds of a Bloom filter.

In step 302, the method can include reading a Bloom filter. In some implementations, the Bloom filter in step 302 corresponds to the Bloom filter described in step 202 and that disclosure is not repeated herein.

In step 304, the method can include computing a false positive rate (FPR) of the Bloom filter received in step 302.

In some implementations, the Bloom filter received in step 302 may be populated after processing all elements to insert into a set. As such, in some implementations, the method can compute the FPR as follows:

$$FPR = {( \frac{s}{t} )}^{k} . \qquad Equation 2$$

In Equation 1, s represents the number of bits set in the Bloom filter, t represents the total number of bits, and k represents the total number of hash functions used to map elements to the Bloom filter.

In some optional implementations, the FPR may be used to terminate the method earlier if a stop condition is met. For example, in some implementations, the method can determine if the current FPR of the Bloom filter is equal to or greater than a target FPR or preconfigured dropout FPR. In some implementations, a dropout FPR refers to a false positive rate such that a Bloom filter having a FPR above such a dropout FPR can be deemed unreliable. Such stop conditions can be implemented to ensure that a Bloom filter having an excessive FPR is not folded (and thus the FPR increased).

In step 306, the method initializes the number of optimal folds to zero.

In step 308, the method determines if the size of the current Bloom filter is above a minimum size.

In some implementations, this minimum size may be a pre-configured minimum size threshold. In some implementations, this threshold ensures that the Bloom filter maintains a minimum number of bits and is not folded to a single bit (or other minimal size). In some implementations, the minimum size can be sized based on the underlying storage mechanism to ensure optimal reading/writing of the Bloom filter.

As illustrated, the check in step 308 may be first executed using the size of the original Bloom filter read in step 302. As illustrated, the method may then execute a loop 320 until various conditions are met. This loop 320 re-computes the total number of bits based on a fold (step 312) and thus results in the total number of bits being reduced. In some implementations, the number of overlapping bits may be probabilistic due to the nature of simulating the folds. Thus, the check in step 308 controls the number of iterations of the loop 320 to ensure that folding a Bloom filter only executes while the total size is above a minimum size. As will be discussed in connection with step 314, the method can also compute the FPR of the Bloom filter as a second termination condition. In brief, loop 320 can iteratively simulate a series of fold operations to generate intermediate Bloom filters and determine when an FPR of a given Bloom filter in the intermediate Bloom filters exceeds a preconfigured threshold

If, in step 308, the method determines that the current size of the Bloom filter is not greater than the minimum size, the method proceeds to step 316 and the ends. In step 316, the method may return the number of folds computed in loop 320 and (optionally) may also fold the Bloom filter using the method of FIG. 2. In some scenarios, if the original Bloom filter size (from step 302) is already equal to or less than the minimum size, the number of folds may be zero and the method may return zero and (if implemented) perform no folds. Similarly, as will be discussed in step 314, a first fold may increase the FPR of the folded Bloom filter too much and thus the method will not increment the number of folds in step 318. In this scenario, the original Bloom filter is left unfolded, and step 316 will return zero and perform no folds. However, as will be discussed next, in all other scenarios, at least one fold will be identified and (optionally) performed.

If during a first execution, in step 308, the method determines that the total bits in the original Bloom filter exceeds the minimum size, the method will proceed to step 310.

In step 310, the method can include computing the expected number of bits set after folding the current Bloom filter. In some implementations, the expected number of bits set after any given fold (b_{s,fold}) can be computed as follows:

$${b}_{s , fold} = \frac{1}{2} {b}_{s , curr} + \frac{1}{2} {b}_{s , curr} ( 1 - {P}_{c} ) = \frac{1}{2} {b}_{s , curr} ( 2 - {P}_{c} ) . \qquad Equation 3$$

In Equation 2, b_{s,curr} represents the number of bits set in the Bloom filter before folding and P_{c} represents the probability of a bit collision. As discussed, the value of b_{s,curr} can be computed by summing the number of set bits in the Bloom filter. In some implementations, the value of P_{c} can be computed by dividing the number of bits set (b_{s,curr}) by the total size of the Bloom filter (size_{curr}). That is:

$${P}_{c} = \frac{{b}_{s , curr}}{{size}_{curr}} . \qquad Equation 4$$

In step 312, the method can include updating the total number of bits. In some implementations, the total number of bits can be computed by halving the current size of the Bloom filter (size_{curr}). That is, the total number of bits in the folded Bloom filter can be computed as:

$${size}_{fold} = \frac{1}{2} {size}_{curr} . \qquad Equation 5$$

In step 314, the method can include computing a new FPR using the expected bits set computed in step 310 and the updated total number of bits computed in step 312. As discussed above, Equation 1 may be used to compute the expected FPR for the folded Bloom filter:

$${FPR}_{folded} = {( \frac{{b}_{s , curr}}{{size}_{fold}} )}^{k} . \qquad Equation 6$$

In some implementations, the method need not perform a fold at this stage, but may rely solely on the size of the Bloom filter and the number of bits set. The method can repeatedly use these values to simulate folding prior to executing a fold.

If the new FPR (FPR_{folded}) is greater than a target FPR, the method executes step 316 and terminates. In this scenario, the given fold has increased the FPR beyond an acceptable FPR and thus the fold is not appropriate. If, however, the new FPR (FPR_{folded}) is below the target FPR, the method proceeds to step 318. In this counter scenario, the new FPR is still acceptable and the fold is appropriate.

In step 318, the method can include incrementing the number of folds by one. The method will then return to step 308 where the total number of bits (as computed in step 312) is above the minimum size. Notably, this new total number of bits will be further reduced in a subsequent iteration of step 312 until step 314 or step 308 trigger step 316, resulting in one or more “folds” of the Bloom filter.

FIG. 5 is a block diagram illustrating computing device 500 (from FIG. 1, discussed above) showing an example of a client or server device used in the various embodiments of the disclosure.

The computing device 500 may include more or fewer components than those shown in FIG. 5, depending on the deployment or usage of the device 500. For example, a server computing device, such as a rack-mounted server, may not include audio interfaces 552, displays 554, keypads 556, illuminators 558, haptic interfaces 562, GPS receivers 564, or cameras/sensors 566. Some devices may include additional components not shown, such as graphics processing unit (GPU) devices, cryptographic co-processors, artificial intelligence (AI) accelerators, or other peripheral devices.

As shown in FIG. 5, the device 500 includes a central processing unit (CPU) 522 in communication with a mass memory 530 via a bus 524. The computing device 500 also includes one or more network interfaces 550, an audio interface 552, a display 554, a keypad 556, an illuminator 558, an input/output interface 560, a haptic interface 562, an optional GPS receiver 564 (and/or an interchangeable or additional GNSS receiver) and a camera(s) or other optical, thermal, or electromagnetic sensors 566. Device 500 can include one camera/sensor 566 or a plurality of cameras/sensors 566. The positioning of the camera(s)/sensor(s) 566 on the device 500 can change per device 500 model, per device 500 capabilities, and the like, or some combination thereof.

In some embodiments, the CPU 522 may comprise a general-purpose CPU. The CPU 522 may comprise a single-core or multiple-core CPU. The CPU 522 may comprise a system-on-a-chip (SoC) or a similar embedded system. In some embodiments, a GPU may be used in place of, or in combination with, a CPU 522. Mass memory 530 may comprise a dynamic random-access memory (DRAM) device, a static random-access memory device (SRAM), or a Flash (e.g., NAND Flash) memory device. In some embodiments, mass memory 530 may comprise a combination of such memory types. In one embodiment, the bus 524 may comprise a Peripheral Component Interconnect Express (PCIe) bus. In some embodiments, the bus 524 may comprise multiple busses instead of a single bus.

Mass memory 530 illustrates another example of computer storage media for the storage of information such as computer-readable instructions, data structures, program modules, or other data. Mass memory 530 stores a basic input/output system (“BIOS”) 540 for controlling the low-level operation of the computing device 500. The mass memory also stores an operating system 541 for controlling the operation of the computing device 500.

Applications 542 may include computer-executable instructions which, when executed by the computing device 500, perform any of the methods (or portions of the methods) described previously in the description of the preceding Figures. In some embodiments, the software or programs implementing the method embodiments can be read from a hard disk drive (not illustrated) and temporarily stored in RAM 532 by CPU 522. CPU 522 may then read the software or data from RAM 532, process them, and store them to RAM 532 again.

The computing device 500 may optionally communicate with a base station (not shown) or directly with another computing device. Network interface 550 is sometimes known as a transceiver, transceiving device, or network interface card (NIC).

The audio interface 552 produces and receives audio signals such as the sound of a human voice. For example, the audio interface 552 may be coupled to a speaker and microphone (not shown) to enable telecommunication with others or generate an audio acknowledgment for some action. Display 554 may be a liquid crystal display (LCD), gas plasma, light-emitting diode (LED), or any other type of display used with a computing device. Display 554 may also include a touch-sensitive screen arranged to receive input from an object such as a stylus or a digit from a human hand.

Keypad 556 may comprise any input device arranged to receive input from a user. Illuminator 558 may provide a status indication or provide light.

The computing device 500 also comprises an input/output interface 560 for communicating with external devices, using communication technologies, such as USB, infrared, Bluetooth™, or the like. The haptic interface 562 provides tactile feedback to a user of the client device.

The optional GPS transceiver 564 can determine the physical coordinates of the computing device 500 on the surface of the Earth, which typically outputs a location as latitude and longitude values.

For the purposes of this disclosure a module is a software, hardware, or firmware (or combinations thereof) system, process or functionality, or component thereof, that performs or facilitates the processes, features, and/or functions described herein (with or without human interaction or augmentation). A module can include sub-modules. Software components of a module may be stored on a computer readable medium for execution by a processor. Modules may be integral to one or more servers, or be loaded and executed by one or more servers. One or more modules may be grouped into an engine or an application.

For the purposes of this disclosure the term “user”, “subscriber” “consumer” or “customer” should be understood to refer to a user of an application or applications as described herein and/or a consumer of data supplied by a data provider. By way of example, and not limitation, the term “user” or “subscriber” can refer to a person who receives data provided by the data or service provider over the Internet in a browser session, or can refer to an automated software application which receives the data and stores or processes the data.

Those skilled in the art will recognize that the methods and systems of the present disclosure may be implemented in many manners and as such are not to be limited by the foregoing exemplary embodiments and examples. In other words, functional elements being performed by single or multiple components, in various combinations of hardware and software or firmware, and individual functions, may be distributed among software applications at either the client level or server level or both. In this regard, any number of the features of the different embodiments described herein may be combined into single or multiple embodiments, and alternate embodiments having fewer than, or more than, all of the features described herein are possible.

Functionality may also be, in whole or in part, distributed among multiple components, in manners now known or to become known. Thus, myriad software/hardware/firmware combinations are possible in achieving the functions, features, interfaces and preferences described herein. Moreover, the scope of the present disclosure covers conventionally known manners for carrying out the described features and functions and interfaces, as well as those variations and modifications that may be made to the hardware or software or firmware components described herein as would be understood by those skilled in the art now and hereafter.

Furthermore, the embodiments of methods presented and described as flowcharts in this disclosure are provided by way of example in order to provide a more complete understanding of the technology. The disclosed methods are not limited to the operations and logical flow presented herein. Alternative embodiments are contemplated in which the order of the various operations is altered and in which sub-operations described as being part of a larger operation are performed independently.

While various embodiments have been described for purposes of this disclosure, such embodiments should not be deemed to limit the teaching of this disclosure to those embodiments. Various changes and modifications may be made to the elements and operations described above to obtain a result that remains within the scope of the systems and processes described in this disclosure.

We claim:

1. A method comprising:
computing a number of folds for a Bloom filter, the Bloom filter having an initial size and a first number of bits set, by simulating a plurality of fold operations using the initial size and the first number of bits set;
executing fold operations on the Bloom filter based on the number of folds to generate a folded Bloom filter, the folded Bloom filter having a size smaller than the initial size; and
storing the folded Bloom filter.

2. The method of claim 1, further comprising determining the initial size based on properties of a data store used to populate the Bloom filter.

3. The method of claim 1, wherein computing the number of folds comprises iteratively simulating a series of fold operations to generate intermediate Bloom filters and determining when a false positive rate (FPR) of a given Bloom filter in the intermediate Bloom filters exceeds a preconfigured threshold.

4. The method of claim 3, further comprising computing an FPR based on a number of expected bits set in the given Bloom filter and a total size of the given Bloom filter.

5. The method of claim 4, wherein the number of expected bits set in the given Bloom filter is computed as:
$$\frac{1}{2} {b}_{s , curr} ( 2 - {P}_{c} ) ,$$
where b_{s,curr} represents a number of bits set in a current Bloom filter and P_{c} represents a probability of a bit collision between the current Bloom filter and the given Bloom filter.

6. The method of claim 1, wherein executing the fold operations comprises collapsing a plurality of fold operations into a single fold operation and executing the single fold operation on the Bloom filter.

7. The method of claim 1, further comprising receiving a query including an element and determining if the element is in a dataset by determining if a plurality of bits of the folded Bloom filter are set.

8. A non-transitory computer-readable storage medium for tangibly storing computer program instructions capable of being executed by a computer processor, the computer program instructions defining steps of:
computing a number of folds for a Bloom filter, the Bloom filter having an initial size and a first number of bits set, by simulating a plurality of fold operations using the initial size and the first number of bits set;
executing fold operations on the Bloom filter based on the number of folds to generate a folded Bloom filter, the folded Bloom filter having a size smaller than the initial size; and
storing the folded Bloom filter.

9. The non-transitory computer-readable storage medium of claim 8, further comprising determining the initial size based on properties of a data store used to populate the Bloom filter.

10. The non-transitory computer-readable storage medium of claim 8, wherein computing the number of folds comprises iteratively simulating a series of fold operations to generate intermediate Bloom filters and determining when a false positive rate (FPR) of a given Bloom filter in the intermediate Bloom filters exceeds a preconfigured threshold.

11. The non-transitory computer-readable storage medium of claim 10, further comprising computing an FPR based on a number of expected bits set in the given Bloom filter and a total size of the given Bloom filter.

12. The non-transitory computer-readable storage medium of claim 11, wherein the number of expected bits set in the given Bloom filter is computed as:
$$\frac{1}{2} {b}_{s , curr} ( 2 - {P}_{c} ) ,$$
where b_{s,curr} represents a number of bits set in a current Bloom filter and P_{c} represents a probability of a bit collision between the current Bloom filter and the given Bloom filter.

13. The non-transitory computer-readable storage medium of claim 8, wherein executing the fold operations comprises collapsing a plurality of fold operations into a single fold operation and executing the single fold operation on the Bloom filter.

14. The non-transitory computer-readable storage medium of claim 8, further comprising receiving a query including an element and determining if the element is in a dataset by determining if a plurality of bits of the folded Bloom filter are set.

15. A system comprising:
a data store storing a dataset;
a computing device configured to:
compute a number of folds for a Bloom filter, the Bloom filter having an initial size and a first number of bits set, by simulating a plurality of fold operations using the initial size and the first number of bits set,
execute fold operations on the Bloom filter based on the number of folds to generate a folded Bloom filter, the folded Bloom filter having a size smaller than the initial size, and
store the folded Bloom filter.

16. The system of claim 15, the computing device further configured to determine the initial size based on properties of a data store used to populate the Bloom filter.

17. The system of claim 15, wherein computing the number of folds comprises iteratively simulating a series of fold operations to generate intermediate Bloom filters and determining when a false positive rate (FPR) of a given Bloom filter in the intermediate Bloom filters exceeds a preconfigured threshold.

18. The system of claim 17, the computing device further configured to compute an FPR based on a number of expected bits set in the given Bloom filter and a total size of the given Bloom filter.

19. The system of claim 18, wherein the number of expected bits set in the given Bloom filter is computed as:
$$\frac{1}{2} {b}_{s , curr} ( 2 - {P}_{c} ) ,$$
where b_{s,curr} represents a number of bits set in a current Bloom filter and P_{c} represents a probability of a bit collision between the current Bloom filter and the given Bloom filter.

20. The system of claim 15, wherein executing the fold operations comprises collapsing a plurality of fold operations into a single fold operation and executing the single fold operation on the Bloom filter.
